(19) United States
(12) Patent Application Publication
(10) Pub. No.: US 2016/0336470 A1
(43) Pub. Date: Nov. 17, 2016

(54) SOLAR CELL MODULE

(71) Applicant: Panasonic Intellectual Property Management Co., Ltd., Osaka (JP)

(72) Inventors: Keisuke Ogawa, Shiga (JP); Tasuku Ishiguro, Osaka (JP); Yukihiro Yoshimine, Osaka (JP); Junpei Irikawa, Osaka (JP)

(73) Assignee: Panasonic Intellectual Property Management Co., Ltd., Osaka (JP)

(21) Appl. No.: 15/218,392

(22) Filed: Jul. 25, 2016

Related U.S. Application Data
(63) Continuation of application No. PCT/JP2015/000599, filed on Feb. 10, 2015.

(30) Foreign Application Priority Data
Feb. 26, 2014 (JP) 2014-035111

(51) Int. Cl. H01L 31/048; H02S 40/22; H01L 31/055

(52) U.S. Cl. CPC H01L 31/0481; H01L 31/055; H02S 40/22

(57) ABSTRACT

This solar cell module is provided with: solar cells; a first protective member winch is provided over a light-receiving-surface side of the solar ceils; a second protective member which is provided over a rear-surface side of the solar cells; and a sealing layer which is provided between the protective members, and which seals the solar cells. A light receiving surface-side area of the sealing layer, said area being positioned further towards the first protective member side than the solar cells, includes: a wavelength conversion material which absorbs light of a specific wavelength, and converts said wavelength: and an ultraviolet-ray absorption material which selectively absorbs ultraviolet rays.

### CROSS-REFERENCE TO RELATED APPLICATIONS

The present application is a continuation under 35 U.S.C. §120 of PCT/JP2015/000599, filed Feb. 10, 2015, which is incorporated herein by reference and which claimed priority to Japanese Patent Application No. 2014-035111 filed on Feb. 26,2014. The present application likewise claims priority under 35 U.S.C. §119 to Japanese Patent Application No. 2014-035111 filed on Feb. 26, 2014, the entire content of which is also incorporated herein by reference.

### TECHNICAL FIELD

The present disclosure relates to a solar cell module.

### BACKGROUND

There has been known a solar cell module that includes a wavelength conversion material which absorbs a light of a specific wavelength and converts the wavelength. By use of such a solar cell module, it is possible to convert, of incident light, light in a wavelength region contributing less to power generation into light in a wavelength region contributing largely to power generation. For example, Patent Literature 1 has disclosed a solar cell module that includes a first sealing layer not containing a wavelength conversion material and a second sealing layer containing a wavelength conversion material between a protective glass and a solar cell.

### CITATION LIST

[Patent Literature]

[Patent Literature 1]

WO2011/148951

### SUMMARY

### Technical Problem

Meanwhile, constituent materials of the solar cell module deteriorate under exposure to ultraviolet rays included in the incident light for a long time. For this reason, the solar cell module has been required to have a function to suppress deterioration due to the ultraviolet rays. Additionally, the solar cell module has been required to further improve incident photoelectric conversion efficiency, of course.

In the solar cell module in Patent Literature 1, it is assumed that the wavelength conversion material may absorb the ultraviolet rays to some extent, but the suppression of the deterioration due to the ultraviolet rays is not sufficiently considered, leaving room for refinement from the viewpoint of durability enhancement. Moreover, the incident photoelectric conversion efficiency is desired to be further improved.

### Solution To Problem

A solar cell module according to the present disclosure includes a solar cell, a first protective member provided over a light-receiving-surface side of the solar cell, a second protective member provided over a rear-surface side of the solar cell, and a sealing layer provided between the respective protective members and sealing the solar cell, in which a light-receiving-surface side area in the sealing layer located closer to a side of the first protective member than the solar cell contains a wavelength conversion material which absorbs light of a specific wavelength and converts the wavelength, and an ultraviolet-ray absorption material which selectively absorbs ultraviolet rays.

### Advantageous Effects of Invention

According to the present disclosure, it is possible to provide a solar cell module which is unlikely to suffer damage from the ultraviolet rays and has high incident photoelectric conversion efficiency.

### BRIEF DESCRIPTION OF DRAWINGS

FIG. 1 is a sectional view of a solar cell module as a first embodiment.

FIG. 2 is an enlarged view of portion A in FIG. 1.

FIG. 3 is an enlarged view of portion B in FIG. 1.

FIG. 4 is a sectional view of a sealing layer as the first embodiment.

FIG. 5 is a sectional view of a sealing layer as a second embodiment.

FIG. 6 is a diagram showing a relationship between a transmittance and a wavelength of light in the sealing layer as the second embodiment.

FIG. 7 is a sectional view of a sealing layer as a third embodiment.

FIG. 8 is a diagram showing a modification example of the third embodiment.

### DESCRIPTION OF EMBODIMENTS

Hereinafter, a description is given of an example of embodiments in detail with reference to the drawings.

The drawings referred to in the embodiments are schematically expressed, and a size ratio or the like of a component drawn in the FIG. may be different from an actual object in some cases. The concrete size ratio or the like should be determined in consideration of the following explanation.

In the description, a “light receiving surface” of a solar cell module and solar cell refers to a surface on which a light is mainly incident (more than 50% up to 100% of the light is incident on the light receiving surface) and a “rear surface” refers to a surface on a side opposite to the light receiving surface. Further, a description “provide a first member on a second member” or the like is not necessarily intended for only a case where the first and second members directly connect with each other, unless otherwise limited. In other words, the description includes a case where another member exists between the first and second members.

### First Embodiment

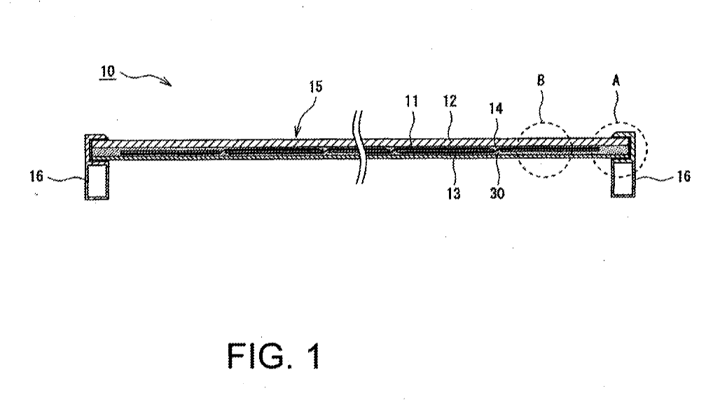

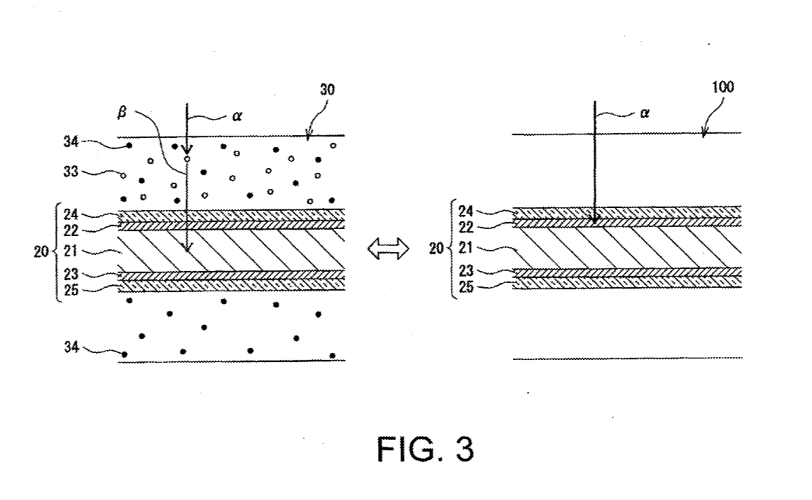

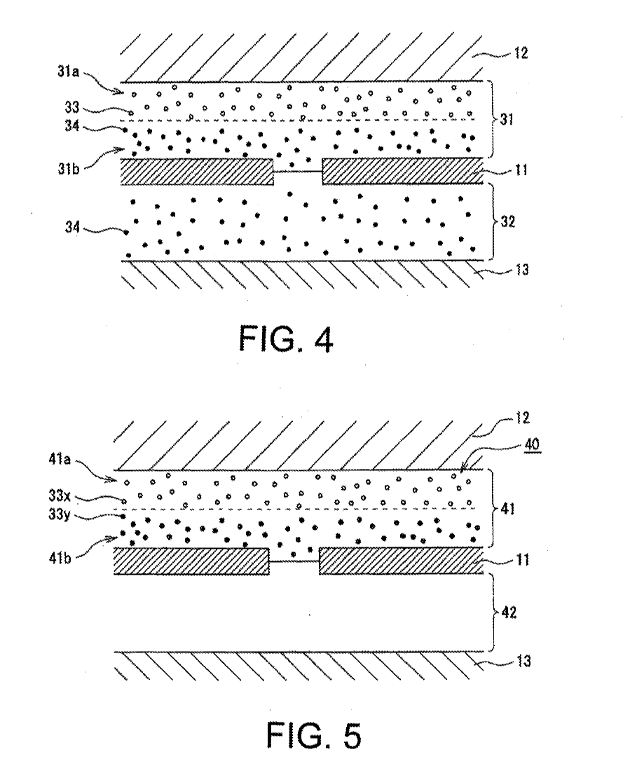

Hereinafter, a detailed description is given of a solar cell module 10 as a first embodiment with reference to FIG. 1 to FIG. 4. FIG. 1 is a sectional view of the solar cell module 10 and FIG . 2 is an enlarged view of portion A in FIG. 1. FIG. 3 is an enlarged view of portion B in FIG. 1 and a structure of related art thereof is shown on the right side by way of comparison. In FIG. 3, each protective member, a conducting wire 14, and an electrode of a solar cell 11 are omitted. FIG. 4 is a sectional view of a sealing layer 30. The conducting wire 14 is omitted in FIG. 4 also. In FIG. 3 and FIG. 4, a wavelength conversion material 33 is denoted by “◯” and an ultraviolet-ray absorption material 34 is denoted by “” for the purpose of illustration.

As shown in FIG. 1, the solar cell module 10 includes the solar cell 11, a first protective member 12 provided over a light-receiving-surface side of the solar cell 11, and a second protective member 13 provided over a rear-surface side of the solar cell 11. The solar cell 11 is sandwiched between the first protective member 12 and the second protective member 13 and is sealed by the sealing layer 30 provided between the respective protective members. As is described later in detail a light-receiving-surface side area 31 in the sealing layer 30 contains the wavelength conversion material 33 which absorbs the light of a specific wavelength and converts the wavelength, and the ultraviolet-ray absorption material 34 which selectively absorbs the ultraviolet rays. The sealing layer 30 is also referred to as a encapsulant layer (encapsulant).

In the embodiment, a plurality of solar cells 11 are arranged substantially on the same plane. The solar cells 11 adjacent to each other are connected in series through the conducting wire 14, which forms a string of the solar cells 11. The conducting wire 14 is bent in a thickness direction of the module between the adjacent solar cells 11, and attached to each of the light receiving surface of one solar cell 11 and the rear surface of the other solar cell 11 by use of an adhesive or the like. A part of the conducting wire 14 is extended from an end of the string and connected with a wiring material for output (not shown). The wiring material is drawn out from, for example, a rear side of the second protective member 13 to be drawn into a terminal box (not shown).

The solar cell 11, the first protective member 12, the second protective member 13, and the sealing layer 30 constitute a solar cell panel 15. The solar cell panel 15 is a plate-like body having the string of the solar cells 11 sandwiched between the respective protective members as described above, and has a substantially rectangular shape in a plane view (when viewed from a direction vertical to the light receiving surface), for example. The second protective member 13 may be bent around to, for example, a lateral face 15a of the solar cell panel 15 to cover the lateral face 15a. The lateral face 15a is a face along a thickness direction of the solar cell panel 15.

Examples of the first protective member 12 may include a member having transparency, such as a glass substrate, a resin substrate, or a resin film, for example. Of these, the glass substrate is preferably used from the viewpoint of fire resistance, durability or the like. A thickness of the glass substrate is not specifically limited, but is preferably about 2 to 6 mm.

Examples of the second protective member 13 may include a transparent member the same as for the first protective member 12 and may include a non-transparent member. The embodiment uses the resin film as the second protective member 13. The resin film is not specifically limited, but is preferably a polyethylene terephthalate (PET) film. From the viewpoint of lowering moisture permeability or the like, the resin film may have formed therein an inorganic compound layer of silica and the like, or a metal layer of aluminium and the like in a case where it is not assumed that the light will be incident on the rear-surface side. A thickness of the resin film is not specifically limited, but is preferably 100 to 300 μm.

The solar cell module 10 preferably includes a frame 16 attached to an end edge of the solar cell panel 15. The frame 16 protects the end edge of the solar cell panel 15 and is used when the solar cell module 10 is installed on a roof or the like. The frame 16 is made of a metal such as stainless-steel, aluminium or the like, for example, and has a main body of a hollow construction and a concave portion in which the end edge of the solar cell panel 15 is fitted. An adhesive 17 of a silicone resin-based adhesive or the like, for example, is filled in a gap between the concave portion of the frame 16 and the solar cell panel 15.

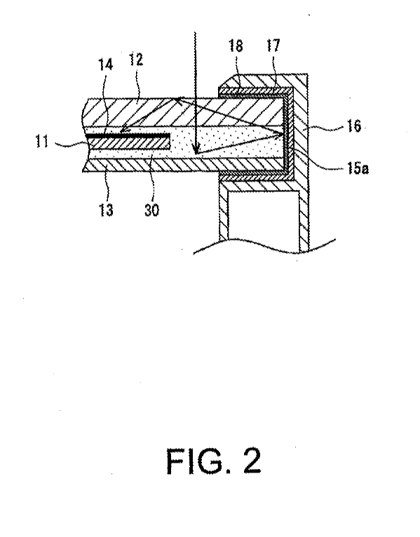

As shown in FIG. 2, the solar cell module 10 preferably includes a reflector 18 which is provided to cover the lateral face 15a of the solar cell panel 15. The reflector 18 reflects the light wavelength-converted by the wavelength conversion material 33 and confines the light to go out from the end edge of the solar cell panel 15 to the panel, functioning to increase the light incident on the solar cell 11. In general, the reflector 18 also reflects light other than the wavelength-converted light. Since the wavelength conversion material 33 having absorbed the light of a specific wavelength isotropically emits the light, installation of the reflector 18 is particularly effective in the solar cell module 10 provided with the wavelength conversion material 33.

The reflector 18 preferably covers substantially the entire lateral face 15a and covers a light receiving surface of the first protective member 12 and a rear surface of the second protective member 13 which are located at the end edge of the solar cell panel 15. However, the reflector 18 is preferably limited to being provided at a portion on each protective member covered by the frame 16. The reflector 18 which is for example, a resin sheet containing a white pigment or the like is attached to the end edge of the solar cell panel 15. Alternatively, a coating film may be formed on the end edge of the solar cell panel 15 or the concave portion of the frame 16 by use of a white paint, and the coating film used as the reflector 18. Moreover, the adhesive 17 to which the white pigment or the like is added may be made to function as the reflector 18.

As shown in FIG. 3, the solar cell 11 includes a photoelectric conversion part 20 which receives sunlight to generate earners. The photoelectric conversion part 20 has, as electrodes for collecting the generated carriers, a light-receiving-surface electrode formed on the light receiving surface of the photoelectric conversion part 20 and a rear-surface electrode formed on the rear surface (neither not shown). Each electrode is electrically connected with the conducting wire 14. However, a structure of the solar cell 11 is not limited thereto, and may have a structure in which the electrode is formed only on the rear surface of the photoelectric conversion part 20, for example. Note that the rear-surface electrode is preferably formed to have an area larger than the light-receiving-surface electrode, and a surface having a larger electrode area (or a surface having the electrode formed thereon) may be said to be the “rear surface” of the solar cell 11.

The photoelectric conversion part 20 has, for example, a semiconductor substrate 21, amorphous semiconductor layers 22 and 23 formed on the substrate, and transparent conductive layers 24 and 25 formed on the amorphous semiconductor layers. Examples of the semiconductor constituting the semiconductor substrate 21 include crystalline silicon (c-Si), gallium arsenide (GaAs), indium phosphide (InP) and the like. Examples of the amorphous semiconductor constituting the amorphous semiconductor layers 22 and 23 include i-type amorphous silicon, n-type amorphous silicon, p-type amorphous silicon and the like. The transparent conductive layers 24 and 25 preferably include a transparent conductive oxide in which metal oxide such as indium oxide (In₂O₃), zinc oxide (ZnO) is doped with tin (Sn), antimony (Sb) or the like.

In the embodiment, an n-type single-crystal silicon substrate is applied to the semiconductor substrate 21. The photoelectric conversion part 20 has a structure in which an i-type amorphous silicon layer, a p-type amorphous silicon layer, and the transparent conductive layer 24 are formed in this order on a light receiving surface of the n-type single-crystal silicon substrate, and an i-type amorphous silicon layer, an n-type amorphous silicon layer, and the transparent conductive layer 25 are formed in this order on a rear surface of the substrate. Alternatively, the p-type amorphous silicon layer may be formed on the rear-surface side of the n-type single-crystal silicon substrate and the n-type amorphous silicon layer may be formed on the light-receiving-surface side of the substrate, respectively. In other words, the photoelectric conversion part 20 has a junction (heterojunction) between the semiconductors in which optical gaps are different from each other. The amorphous silicon layer forming the heterojunction (thickness: several am to several tens nm) generally absorbs the light having the wavelength of 600 nm or less.

As described later in detail, the wavelength conversion material 33 contained in the sealing layer 30 preferably absorbs and wavelength-converts the light of a wavelength having an energy equal to or more than a bandgap of the amorphous semiconductor layers 22 and 23 which are each a heterojunction layer.

Hereinafter, a description is further given of the structure of the sealing layer 30 with reference to FIG. 3 and FIG. 4, adequately.

The sealing layer 30 which is provided between each protective member and the solar cell 11 functions to prevent the moisture or the like from contacting the solar cell 11. The sealing layer 30 contains the wavelength conversion material 33 and the ultraviolet-ray absorption material 34 in at least the light-receiving-surface side area 31. As shown in FIG. 3 and FIG. 4, in the embodiment, the ultraviolet-ray absorption material 34 is also contained in a rear-surface side area 32.

Here, the light-receiving-surface side area 31 is an area in the sealing layer 30 located closer to the first protective member 12 side than the solar cell 11. The rear-surface side area 32 is an area in the sealing layer 30 located closer to the second protective member 13 side than the solar cell 11. A description is given later of preferable concentration distributions of the wavelength conversion material 33 and ultraviolet-ray absorption material 34 in the respective areas of the sea ling layer 30, particularly, the light-receiving-surface side area 31.

The sealing layer 30 is preferably formed in a laminating process described later using a resin sheet constituting the light-receiving-surface side area 31 (hereinafter, referred to as “resin sheet 31”) and a resin sheet constituting the rear-surface side area 32 (hereinafter, referred to as “resin sheet 32”). In FIG. 4, a boundary between the light-receiving-surface side area 31 and the rear-surface side area 32 is clearly defined, but the boundary may not be confirmed in some cases depending on a kind of the resin and conditions of the laminating process.

The resin constituting the sealing layer 30 preferably has excellent adhesion to each protective member and the solar cell 11, and is unlikely to be permeable to moisture. Specifically, examples of the resins include an olefin-based resin obtained by polymerizing at least one kind selected from a olefin having a carbon number of 2 to 20 (e.g., polyethylene, polypropylene, a random or block copolymer of ethylene and other a olefin, etc.), an ester-based resin (e.g., polycondensate of polyol and polycarboxylic acid or acid anhydride/lower alkyl ester, etc.), a urethane-based resin (e.g., polyaddition compound of polyisocyanate and active hydrogen group-containing compound (diol, polyol, dicarboxylic acid, polycarboxylic acid, polyamine, polythiol, etc.) or the like), an epoxy-based resin (e.g., ring-opening polymer of polyepoxide, polyaddition compound of polyepoxide and an active hydrogen group-containing compound, etc.), and a copolymer of a olefin and carboxylic acid vinyl, acrylic acid ester, or other vinyl monomer.

Of these, particularly preferable are the olefin-based resin (in particular, polymer including ethylene), and the copolymer of a olefin and carboxylic acid vinyl. Ethylene vinyl acetate copolymer (EVA) is particularly preferable as the copolymer of a olefin and carboxylic acid vinyl.

The thickness of the sealing layer 30 is not specifically limited, but the thicknesses of the light-receiving-surface side area 31 arid the rear-surface side area 32 are each preferably about 100 to 600 μm. A high crosslink density resin is preferably used for the light-receiving-surface side area 31 arid a low crosslink density resin or non-crosslinked resin is preferably used for the rear-surface side area 32, depending on the structure or an intended purpose (usage environment) of the solar cell module 10.

A refractive index of the sealing layer 30 is preferably set to be higher than a refractive index of an outermost layer of the first protective member 12 at the light-receiving-surface side area 31 containing the wavelength conversion material 33. In other words, in a case where the first protective member 12 is the glass substrate, the refractive index of the light-receiving-surface side area 31 is preferably set to be higher than the refractive index of a glass surface. The refractive index of the light-receiving-surface side area 31 can be adjusted by. for example, suitably changing a composition of resin components. Since the wavelength conversion material 33 having absorbed the light of a specific wavelength isotropically emits the light, there exists light passing through the glass to go out from the panel, but a totally reflected component at the glass surface is increased by the adjustment of the refractive index, preventing the relevant light from going out.

The wavelength conversion material 33, which is a material absorbing the light of a specific wavelength and converting the wavelength as described above, converts light in a wavelength region contributing less to power generation into light in a wavelength region contributing largely to power generation. The wavelength conversion material 33 absorbs ultra violet rays that are light of a shorter wavelength than 380 nm, for example, and converts into light of a longer wavelength (e.g., 400 to 800 nm). In this case, the wavelength conversion material 33 also contributes to suppressing deterioration of the constituent material by the ultraviolet rays.

The wavelength conversion material 33 is preferably one that absorbs the ultraviolet rays and emits visible light, but may be a material that absorbs the visible light or infrared light. In general the wavelength conversion material 33 converts the shorter wavelength into the longer wavelength, but may be a material that performs a so-called upconversion emission in which the longer wavelength is converted into the shorter wavelength. A preferable converted wavelength depends on the kind of solar cell 11.

In a case where the solar cell 11 has the heterojunction layer, the wavelength conversion material 33 preferably absorbs and wavelength-converts the light of a wavelength having an energy equal to or more than a bandgap of the heterojunction layer, as described above, in oilier words, the wavelength conversion material 33 preferably converts the light of the wavelength absorbed into the heterojunction layer. In the embodiment, the wavelength conversion material 33 is preferably used which can absorb light α of a wavelength λ_{α} absorbed by the amorphous semiconductor layers 22 and 23 which are each the heterojunction layer and convert into light β of a wavelength λ_{β} not absorbed by the semiconductor layers (see FIG. 3). λ_{α} is equal to or less than 600 nm, for example. On the other hand, in a case of using a sealing layer 100 in which the wavelength conversion material 33 like this does not exist, a part of the light a is absorbed by the amorphous semiconductor layers 22 and 23.

Concrete examples of the wavelength conversion material 33 include semiconductor nanoparticles (quantum dot), luminescent metal complexes, organic fluorescent dyes and the like. Examples of the semiconductor nanoparticle include nanoparticles of zinc oxide (ZnO), cadmium selenide (CdSe), cadmium telluride (CdTe), gallium nitride (GaN), yttrium oxide (Y₂O₃), indium phosphide (InP) and the like. Examples of the luminescent metal complex include an Ir complex such as [Ir(bqn)₃](PF₆)₃, [Ir(dpbpy)₃](PF₆)₃ or the like, a Ru complex such as [Ru(bqn)₃](PF₆)₃, [Ru(bpy)₃](ClO₄)₂ or the like, a Eu complex such as [Eu(FOD)₃]phen, [Eu(TFA)₃]phen or the like, and a Tb complex such as [Tb(FOD)₃]phen, [Tb(HFA)₃]phen or the like. Examples of the organic fluorescent dye include a rhodamine-based dye, a coumarin-based dye, a fluorescein-based dye, a perylene-based dye and the like.

The ultraviolet-ray absorption material 34, which is a material selectively absorbing ultra violet rays that are light of a shorter wavelength than 380 nm, does not have a wavelength-conversion function like the wavelength conversion material 33. In other words, the ultraviolet-ray absorption material 34 is a material only absorbing the ultraviolet rays and not emitting the light. Moreover, the ultraviolet-ray absorption material 34, which selectively absorbs the ultraviolet rays, for example, does not absorb the light converted by the wavelength conversion material 33 into the longer wavelength than in an ultraviolet region.

Concrete examples of the ultraviolet-ray absorption material 34 include a benzotriazole-based compound, a benzophenone-based compound, a salicylate-based compound, a cyanoacrylate-based compound, a nickel-based compound, a triazine-based compound, and the like. These are inexpensive compared to the wavelength conversion material 33. In a case where the ultraviolet rays are intended to be cut by only the wavelength conversion material 33, a cost increases significantly because a large amount of the wavelength conversion material 33 is required, but using in combination the wavelength conversion material 33 and the ultraviolet-ray absorption material 34 makes it possible to inexpensively provide a high functional product.

The embodiment is based on the assumption that one kind of each of the wavelength conversion material 33 and the ultraviolet-ray absorption material 34 is used. In addition, the wavelength conversion material 33 is assumed to absorb ultraviolet rays and convert into light of a visible region. In other words, the wavelength conversion material 33 and the ultraviolet-ray absorption material 34 compete with each other in absorbing the ultraviolet rays.

Hereinafter, a description is given of preferable concentration distributions of the wavelength conversion material 33 and the ultraviolet-ray absorption material 34 in the respective areas of the sealing layer 30. In the following description, a concentration of the wavelength conversion material 33 is designated as “ρ₃₃”, and a concentration of the ultraviolet-ray absorption material 34 is designated as “ρ₃₄”.

In examples shown in FIG. 3 and FIG. 4, the wavelength conversion material 33 is contained in only the light-receiving-surface side area 31, but not contained in the rear-surface side area 32 of the sealing layer 30. On the other hand, the ultraviolet-ray absorption material 34 is contained in both the light-receiving-surface side area 31 and the rear-surface side area 32. Further, the wavelength conversion material 33 is contained in only a first area 31a, and the ultraviolet-ray absorption material 34 is contained in only a second area 31b (see FIG. 4). Here, the first area 31a is an area adjacent to the first protective member 12 in the light-receiving-surface side area 31. The second area 31b is an area adjacent to the solar cell 11 in the light-receiving-surface side area 31. A boundary between the first area 31a and the second area 31b is assumed to be just in the middle of the thickness of the light-receiving-surface side area 31.

ρ₃₃ and ρ₃₄ in the light-receiving-surface side area 31 may be substantially uniform (see FIG. 3), but preferably differ between the first area 31a and the second area 31b from the viewpoint of usage efficiency improvement of the wavelength conversion material 33 (see FIG. 4). Note that FIG. 4 shows an extreme example for the purpose of clarify of the figure, and preferable examples of the concentration distributions of the wavelength conversion material 33 and the ultraviolet-ray absorption material 34 are not limited those shown in the figure.

In a case where the wavelength conversion material 33 and the ultraviolet-ray absorption material 34 exist in the first area 31a and the second area 31b, a ratio of ρ₃₃ to ρ₃₄ in the first area 31a (ρ₃₃/ρ₃₄) is preferably higher than that in the second area 31b. For example, ρ₃₃<ρ₃₄ may hold in the first area 31a and the second area 31b, but in this case, at least the above relationship is preferably met.

ρ₃₃ is preferably higher than ρ₃₄ in the first area 31a. Moreover, ρ₃₄ is preferably higher than ρ₃₃ in the second area 31b. By making ρ₃₃>ρ₃₄ hold in the first area 31a and ρ₃₃<ρ₃₄ hold in the second area 31b, the wavelength conversion material 33 can be used more effectively. In other words, it is possible to further suppress the effect of the ultraviolet-ray absorption material 34 preventing the ultraviolet ray absorption by the wavelength conversion material 33. Additionally, the ultraviolet rays which the wavelength conversion material 33 cannot convert may be absorbed by the ultraviolet-ray absorption material 34 contained in the second area 31b in large amounts.

For example, ρ₃₃ may be substantially even in the light-receiving-surface side area 31 and ρ₃₄ may be higher in the second area 31b than in the first area 31a (in other words, ρ₃₄ may be lower in the first area 31a than in the second area 31b). Moreover, may be substantially even in the light-receiving-surface side area 31, and ρ₃₃ maybe lower in the second area 31b than in the first area 31a (in other words, ρ₃₃ may be higher in the first area 31a than in the second area 31b).

It is particularly preferable that ρ₃₃ is higher in the first area 31a than in the second area 31b and ρ₃₄ is higher in the second area 31b than in the first area 31a. That is, in the light-receiving-surface side area 31, a non-uniform concentration distribution exists in either the wavelength conversion material 33 or the ultraviolet-ray absorption material 34. Concentration gradients of the respective materials preferably have relationships that are opposite to each other with respect to the thickness direction of the light-receiving-surface side area 31. For example, the closer to the solar cell 11 from the first protective member 12, the more ρ₃₃ may be decreased gradually or in a stepwise fashion. Moreover, the closer to the solar cell 11 from the first protective member 12, the more ρ₃₄ may be increased gradually or in a stepwise fashion.

Concretely, ρ₃₃ in the first area 31a is preferably 0.1 to 15 wt % with respect to a total weight of the first area 31a and more preferably 1.5 to 10 wt %, in a case where the wavelength conversion material 33 is an inorganic system compound such as a semiconductor nanoparticle, a luminescent metal complex and the like. ρ₃₃ is preferably 0.02 to 2.0 wt % with respect to the total weight of the first area 1a and more preferably 0.05 to 0.8 wt % in a case where the wavelength conversion material 33 is an organic system compound such as an organic fluorescent dye and the like. ρ₃₄ in the first area 31a is preferably 0 to 0.05 wt % with respect to the total weight of the first area 31a and more preferably 0 to 0.02 wt %.

ρ₃₃ in the second area 31b is preferably 0 to 1.5 wt % with respect to a total weight of the second area 31b and more preferably 0 to 0.1 wt % in a case where the wavelength conversion material 33 is an inorganic system compound. ρ₃₃ is preferably 0 to 0.05 wt % with respect to the total weight of the second area 31b and more preferably 0 to 0.02 wt % in a case where the wavelength conversion material 33 is an organic system compound. ρ₃₄ in the second area 31b is preferably 0.002 to 5 wt % with respect to the total weight of the second area 31b and more preferably 0.005 to 3 wt %.

ρ₃₄ in the rear-surface side area 32, for example, may be substantially the same as ρ₃₄ in the second area 31b. Since an amount of the ultraviolet rays is smaller in the rear-surface side area 32 than in the light-receiving-surface side area 31, if maybe preferably set that ρ₃₄ in the rear-surface side area 32<ρ₃₄ in the second area 31b holds.

Note that an antioxidizing agent or a flame retardant besides the wavelength conversion material 33 and the ultraviolet-ray absorption material 34, may be added to the sealing layer 30. A pigment of titanium oxide or the like may be added to the rear-surface side area 32 in a case where it is not assumed that the light will be incident on the rear-surface side.

The solar cell module 10 including the above structure can be manufactured by laminating the string of the solar cells 11 connected by the conducting wire 14, by use of the resin sheet constituting the first protective member 12, the second protective member 13, and the sealing layer 30. In a laminate device, the first protective member 12, the resin sheet 31, the string of the solar cells 11, the resin sheet 32, and the second protective member 13 are laminated in this order on a heater, for example. This laminated body is heated to about 150° C. in a vacuum state. After that, heating is continued under an atmospheric pressure with each constituent member being pressed to the heater side to cross-link resin components in the resin sheet, obtaining the solar cell panel 15. Finally, the reflector 18. the terminal box, the frame 16 and the like are attached to the solar cell panel 15 to obtain the solar cell module 10.

The concentration gradients of the wavelength conversion material 33 and the ultraviolet-ray absorption material 34 in the light-receiving-surface side area 31 can be formed by using a plurality of resin sheets as the resin sheet 31 in which contents of the wavelength conversion material 33 and the ultraviolet-ray absorption material 34 are different from each other, for example. As a concrete example, in the laminating process, the resin sheet containing only the wavelength conversion material 33 may be arranged on the first protective member 12 side, and the resin sheet containing only the ultraviolet-ray absorption material 34 may be arranged on the solar cell 11 side.

As described above, according to the solar-cell module 10 including the above structure, damage is unlikely to be suffered from the ultraviolet rays and the high incident photoelectric conversion efficiency can be obtained. In other words, in the solar cell module 10, deterioration of the constituent material due to the ultraviolet rays is suppressed while allowing efficient use of the wavelength conversion material 33 by appropriately setting the concentration distributions of the wavelength conversion material 33 and the ultraviolet-ray absorption material 34 in the sealing layer 30. Moreover, using the wavelength conversion material 33 and the ultraviolet-ray absorption material 34 in combination makes it possible to inexpensively provide a high functional product which has excellent durability and photoelectric conversion efficiency.

### Second Embodiment

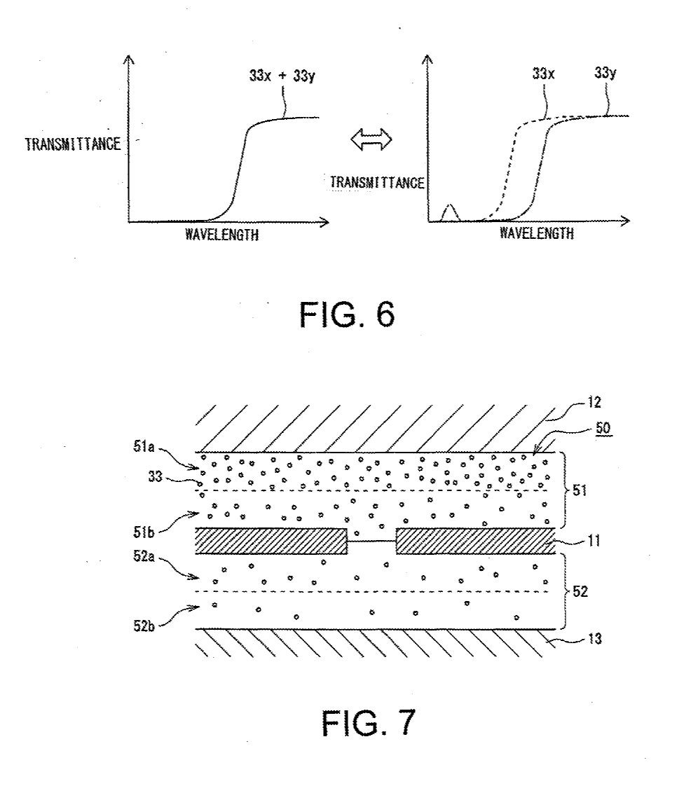

Hereinafter, a detailed description is given of a second embodiment with reference to FIG. 5 and FIG. 6. FIG. 5 is a sectional view of a sealing layer 40 similar to FIG. 4 (ultraviolet-ray absorption material 34 is omitted). FIG. 6 is a diagram showing a relationship between a transmittance and a wavelength of light in the sealing layer 40. FIG. 6 shows on the right a case of a sealing layer which contains only each of a first wavelength conversion material 33x and a second wavelength conversion material 33y by way of comparison, in the following description, a different point from the first embodiment is mainly explained, and the same components as the first embodiment are designated by the same reference signs with duplicated description being omitted.

In the second embodiment, a structure of the sealing layer 40 is different from the sealing layer 30 in the first embodiment. Concretely, the sealing layer 40 is different in from the sealing layer 30, which contains one kind wavelength conversion material 33, in that it contains two kinds, namely the first wavelength conversion material 33x and the second wavelength conversion material 33y. In FIG. 5, the ultraviolet-ray absorption material 34 is omitted, but the preferable concentration distribution of the ultraviolet-ray absorption material 34 in the sealing layer 40 is the same as ρ₃₄ in the first area 31a of the first embodiment, for example.

As shown in FIG. 5, the first wavelength conversion material 33x and the second wavelength conversion material 33y are contained in a light-receiving-surface side area 41 in the sealing layer 40. The second wavelength conversion material 33y is a material which absorbs and wavelength-converts light, of a longer wavelength than the first wavelength conversion material 33x. The first wavelength conversion material 33x and the second wavelength conversion material 33y preferably have at least the maximal absorption wavelength not overlapping each other. Moreover, at least the maximum emission wavelength of the first wavelength conversion material 33x and the maximal absorption wavelength of the second wavelength conversion material 33y preferably do not overlap each other. Of course, it is particularly preferable that the first wavelength conversion material 33x substantially does not absorb the ultraviolet rays or the like absorbed by the second wavelength conversion material 33y, and the second wavelength conversion material 33y substantially does not absorb the light wavelength-converted by the first wavelength conversion material 33x.

The first wavelength conversion material 33x and the second wavelength conversion material 33y are not specifically limited in individual materials so long as a combination thereof satisfies the above relationship, and the same material as the wavelength conversion material 33 may be used, for example. As an example of preferable combination, a perylene-based dye may be used for the first wavelength conversion material 33x and a fluorescein-based dye may be used for the second wavelength conversion material 33y. To the first wavelength conversion material 33x and the second wavelength conversion material 33y, materials may be applied which are of the same kind as each other (e.g., perylene-based dye) and different from each other in wavelength conversion characteristics (absorption wavelength and emission wavelength).

As shown in FIG. 6, two kinds of material that are the first wavelength conversion material 33x and the second wavelength conversion material 33y are used to improve a conversion efficiency of the ultraviolet rays which contribute less to power generation and deteriorate the constituent material, for example. In a case of the sealing layer containing only the first wavelength conversion material 33x, the ultraviolet rays close to the visible region, for example, cannot be sufficiently converted in some cases. On the other hand, in a case of the sealing layer containing only the second wavelength conversion material 33y, a part of the ultraviolet rays of a shorter wavelength, for example, is difficult to convert. Using the first wavelength conversion material 33x and the second wavelength conversion material 33y in combination makes it possible to remove disadvantages in a case where only one of the two is used alone.

Hereinafter, a description is given of preferable concentration distributions of the first wavelength conversion material 33x and the second wavelength conversion material 33y in the respective areas of the sealing layer 40. In the following description, a concentration of the first wavelength conversion material 33x is designated as “ρ₃₃ₓ”, and a concentration of the second wavelength conversion material 33y is designated as “ρ_{33y}”.

In an example shown in FIG. 5, the first wavelength conversion material 33x and the second wavelength conversion material 33y are contained only in the light-receiving-surface side area 41. However, the first wavelength conversion material 33x and the second wavelength conversion material 33y may be contained in a rear-surface side area 42. For example, the rear-surface side area 42 may have the respective materials contained therein at substantially the same concentration. Alternatively, in the rear-surface side area 42, ρ₃₃ₓρ_{33y} may hold or only the second wavelength conversion material 33y may be contained.

ρ33x and ρ_{33y} in the light-receiving-surface side area 41 maybe substantially uniform, but ρ₃₃ₓ/ρ_{33y} in the first area 41a is preferably higher than ρ₃₃ₓ/ρ_{33y} in the second area 41b from the viewpoint of protection of the second wavelength conversion material 33y. Further, ρ₃₃ₓ is preferably higher in the first area 41a than ρ_{33y}, and ρ_{33y} is preferably higher in the second area 41b than ρ₃₃ₓ. The second wavelength conversion material 33y converting the light of a longer wavelength is likely to suffer damage from the light of a shorter wavelength compared to the first wavelength conversion material 33x, but deterioration of the second wavelength conversion material 33y can be suppressed by applying the relevant concentration distribution. In other words, the first wavelength conversion material 33x converts the light of a shorter wavelength which deteriorates the second wavelength conversion material 33y, thus protecting the second wavelength conversion material 33y. The light of a longer wavelength which the first wavelength conversion material 33x cannot convert may be converted by the second wavelength conversion material 33y contained in the second area 41b in large amounts.

For example, ρ₃₃ₓ may be substantially uniform in the light-receiving-surface side area 41 and ρ_{33y} may be higher in the second area 41b than in the first area 41a (in other words, ρ₃₃ₓ may be lower in the first area 41a than in the second area 41b). Moreover, ρ_{33y} may be substantially even in the light-receiving-surface side area 41 and ρ₃₃ₓ may be lower in the second area 41b than in the first area 41a (in other words, and ρ₃₃ₓ may be higher in the first area 41a than in the second area 41b).

It is particularly preferable that ρ₃₃ₓ is higher in the first area 41a than the second area 41b and that ρ_{33y} is higher in the second area 41b than in the first area 41a. That is, in the light-receiving-surface side area 41, a non-uniform concentration distribution exists in either the first wavelength conversion material 33x or the second wavelength conversion material 33y. Concentration gradients of the respective materials preferably have relationships that are opposite to each other with respect to the thickness direction of the light-receiving-surface side area 41. For example, the closer to the solar cell 11 from the first protective member 12, the more ρ₃₃ₓ may be decreased gradually or in a stepwise fashion. Moreover, the closer to the solar cell 11 from the first protective member 12, the more ρ_{33y} may be increased gradually or in a stepwise fashion.

Concretely, ρ₃₃ₓ in the first area 41a is preferably 0.1 to 15 wt % with respect to a total weight of the first area 41a and more preferably 1.5 to 10 wt % in a case where the wavelength conversion material 33x is an inorganic system compound. ρ₃₃ₓ is preferably is 0.02 to 2.0 wt % with respect to the total weight of the first area 41a and more preferably 0.05 to 0.8 wt % in a case where the wavelength conversion material 33x is an organic system compound. ρ_{33y} in the first area 41a is preferably 0 to 1.5 wt % with respect to the total weight of the first area 41a and more preferably 0 to 0.1 wt % in a case where the wavelength conversion material 33y is an inorganic system compound. ρ_{33y} is preferably is 0 to 0.05 wt % with respect to the total weight of the first area 41a and more preferably 0 to 0.02 wt % in a case where the wavelength conversion material 33y is an organic system compound.

ρ₃₃ₓ in the second area 41b is preferably 0 to 1.5 wt % with respect to a total weight of the second area 41b and more preferably 0 to 0.1 wt % in a case where the wavelength conversion material 33x is an inorganic system compound. ρ₃₃ₓ is preferably 0 to 0.05 wt % with respect to the total weight of the second area 41b and more preferably 0 to 0.02 wt % in a case where the wavelength conversion material 33x is an organic system compound. ρ_{33y} in the second area 41b is preferably 0.1 to 15 wt % with respect to the total weight of the second area 41b and more preferably 1.5 to 10 wt % in a case where the wavelength conversion material 33y is an inorganic system compound. ρ_{33y} is preferably is 0.02 to 2.0 wt % with respect to the total weight of the second area 41b and more preferably 0.05 to 0.8 wt % in a case where the wavelength conversion material 33y is an organic system compound.

Note that in a case where it is required for an emission wavelength of the first wavelength conversion material 33x and an absorption wavelength of the second wavelength conversion material 33y to overlap each other in large amounts, concentration distributions described above may be inverted. In other words, in this case, ρ₃₃ₓ/ρ_{33y} in the first area 41a is set to be lower than ρ₃₃ₓ/ρ_{33y} in the second area 41b to suppress duplicated wavelength conversion, enhancing the wavelength conversion efficiency.

In the embodiment, the case is shown where two kinds of material, namely the first wavelength conversion material 33x arid the second wavelength conversion material 33y, are used, but three or more lands of wavelength conversion materials may be used.

### Third Embodiment

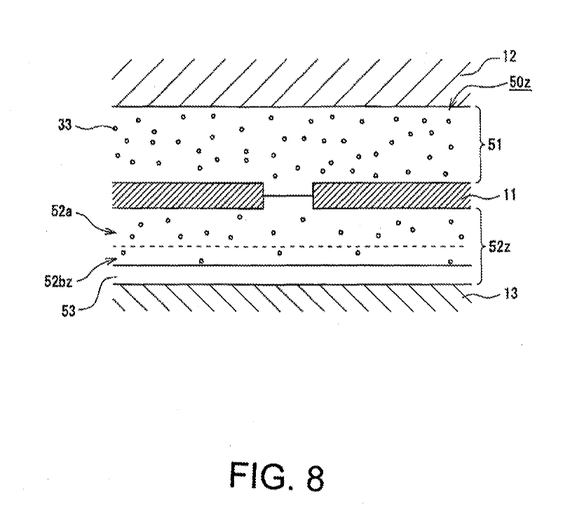

Hereinafter, a detailed description is given of a third embodiment with reference to FIG. 7 and FIG. 8. FIG. 7 is a sectional view of a sealing layer 50 similar to FIG. 4 (ultraviolet-ray absorption material 34 is omitted). FIG. 8 is a diagram showing a modification example of the sealing layer 50. In the following description, a different point from the above embodiments is mainly explained, and the same components as the above embodiments are designated by the same reference signs with duplicated description being omitted.

In the third embodiment, a structure of the sealing layer 50 is different from the sealing layers in the first and second embodiments. The sealing layer 50 contains one kind of wavelength conversion material 33 in common with the sealing layer 30, but is different from the sealing layer 30 in a point that, the wavelength conversion material 33 is also contained in a rear-surface side area 52. The concentration of the wavelength conversion material 33 in a light-receiving-surface side area 51 is preferably lower in the second area 51b than in the first area 51a. In FIG. 7 and FIG. 8, the ultraviolet-ray absorption material 34 is omitted, but the preferable concentration distribution of the ultra violet-ray absorption material 34 in the sea ling layer 50 is the same as that of the first embodiment.

As shown in FIG. 7, the concentration of the wavelength conversion material 33 in the rear-surface side area 52 is preferably lower in a fourth area 52b adjacent to the second protective member 13 than in a third area 52a adjacent to the solar cell 11 (a boundary between the third area 52a and the fourth area 52b is assumed to be just in the middle of the thickness of the rear-surface side area 32). That is, in the sealing layer 50, the concentration of the wavelength conversion material 33 is decreased gradually or in a stepwise fashion from the first protective member 12 side toward the second protective member 13 side.

This allows efficient use of the wavelength conversion material 33 to be improved. In other words, since the closer to the second protective member 13, the more a ratio of the light wavelength-converted by the wavelength conversion material 33 increases, even if the wavelength conversion material 33 exists in such an area, the probability is low that non-converted light will be absorbed by the wavelength conversion material 33. Therefore, an amount of the wavelength conversion material 33 to be added is reduced for the area. Moreover, even if one kind wavelength conversion material 33 is used, a part of the absorption wavelength of the light and a part of the emission wavelength may overlap each other in some cases, and in this case, duplicated wavelength conversion will probably occur. In other words, in an area where the ratio of the wavelength-converted light is large, the concentration of the wavelength conversion material 33 is reduced to suppress the duplicated wavelength conversion.

In an example shown in FIG. 8, in a fourth area 52bz in a rear-surface side area 52z, an area 53 not containing the wavelength conversion material 33 is formed only in the vicinity of the second protective member 13. The area 53 functions as, for example, an anchor coat layer improving adhesiveness between the sealing layer 50 and the second protective member 13, and can be formed using a resin sheet having a composition different from other areas. Additionally, in the example shown in FIG. 8, the concentration of the wavelength conversion material 33 in the light-receiving-surface side area 51 is substantially uniform. As a further design modification example, it may be that only the area 53 does not contain the wavelength conversion material 33 and the concentrations of the wavelength conversion materials 33 in other areas are substantially uniform.

### REFERENCE SIGNS LIST

10 solar cell module, 11 solar cell, 12 first protective member, 13 second protective member, 14 conducting wire, 15 solar cell panel, 15a lateral face, 16 frame, 17 adhesive, 18 reflector, 20 photoelectric conversion part, 21 semiconductor substrate, 22, 23 amorphous semiconductor layer, 24, 25 transparent conductive layer, 30, 40, 50 sealing layer, 31, 41, 51, 61 light-receiving-surface side area, 31a, 41a, 51a first area, 31b, 41b, 51b second area, 32, 42, 52, 52z, 62 rear-surface side area, 33 wavelength conversion material, 33x first wavelength conversion material, 33y second wavelength conversion material, 34 ultraviolet-ray absorption material, 52a third area, 52b, 52bz fourth area, 53 area

1. A solar cell module comprising:
a solar cell:
a first protective member provided over a light-receiving-surface side of the solar cell;
a second protective member provided over a rear-surface side of the solar cell; and
a sealing layer provided between the respective protective members and sealing the solar cell,
wherein
a light-receiving-surface side area in the sealing layer located closer to a side of the first protective member than the solar cell contains a wavelength conversion material which absorbs light of a specific wavelength and converts the wavelength, and an ultraviolet-ray absorption material which selectively absorbs ultraviolet rays.

2. The solar cell module according to claim 1, wherein
a concentration of at least one kind of the wavelength conversion material is higher at a first area adjacent to the first protective member in the light-receiving-surface side area than a concentration of the ultraviolet-ray absorption material, and
the concentration of the ultraviolet-ray absorption material is higher at a second area adjacent to the solar cell in the light-receiving-surface side area than the concentration of at least one kind of the wavelength conversion material.

3. The solar cell module according to claim 2, wherein
the concentration of at least one kind of the wavelength conversion material in the light-receiving-surface side area is lower in the second area adjacent to the solar cell than in the first area adjacent to the first protective member.

4. The solar cell module according to claim 2, wherein
the concentration of the ultra violet-ray absorption material is higher in the second area than in the first area.

5. The solar cell module according to claim 2, wherein
the wavelength conversion material includes a first wavelength conversion material and a second wavelength conversion material which absorbs and wavelength-converts light of a longer wavelength than the first wavelength conversion material,
a concentration of the first wavelength conversion material is higher in the first area than a concentration of the second wavelength conversion material, and
the concentration of the second wavelength conversion material is higher in the second area than the concentration of the first wavelength conversion material.

6. The solar cell module according to claim 2, wherein
the wavelength conversion material is further contained in a rear-surface side area in the sealing layer located closer to a side of the second protective member than the solar cell, and
a concentration of the wavelength conversion material in the rear-surface side area is lower in a fourth area adjacent to the second protective member than in a third area adjacent to the solar cell.

7. The solar cell module according to claim 1, wherein
the solar cell includes a heterojunction layer, and
the wavelength conversion material absorbs and wavelength-converts light of a wavelength having an energy equal to or more than a bandgap of the heterojunction layer.

8. The solar cell module according to claim 1, wherein
a retractive index of an area containing the wavelength conversion material in the sealing layer is higher than a refractive index of an outermost layer of the first protective member.

9. The solar cell module according to claim 1, further comprising a reflector which is provided to cover a lateral face of a solar cell panel and reflects light wavelength-converted by the wavelength conversion material, the solar cell panel being constituted by the solar cell, the first protective member, the second protective member, and the sealing layer.
